(19) United States
(12) Patent Application Publication
(10) Pub. No.: US 2026/0245805 A1
(43) Pub. Date: Aug. 20, 2026

(54) Paired Capacitor and Manufacturing Method Thereof

(71) Applicant: UNITED MICROELECTRONICS CORP., Hsin-Chu City (TW)

(72) Inventors: Chieh-Ming Tang, Hsinchu County (TW); Hui-Sheng Chang, Hsinchu City (TW)

(73) Assignee: UNITED MICROELECTRONICS CORP., Hsin-Chu City (TW)

(21) Appl. No.: 19/083,406

(22) Filed: Mar. 18, 2025

(30) Foreign Application Priority Data
Feb. 18, 2025 (TW) 114105917

(51) Int. Cl. H01G 4/38; H01G 4/005; H01G 4/30

(52) U.S. Cl. CPC H01G 4/38; H01G 4/005; H01G 4/30

(57) ABSTRACT

The invention provides a paired capacitor comprising a substrate with a left region, a middle region, and a right region defined thereon, wherein the middle region is located between the left region and the right region; a first capacitor structure comprising a first lower electrode pattern and a first upper electrode pattern in different regions and layers along a vertical direction; and a second capacitor structure comprising a second lower electrode pattern and a second upper electrode pattern similarly arranged.

### BACKGROUND OF THE INVENTION

### 1. Field of the Invention

The invention relates to the field of semiconductors, and more particularly, the invention relates to a paired capacitor composed of MOM capacitors with alternating layered patterns, which can reduce the problem of inconsistent capacitance values on the two sides caused by process errors.

### 2. Description of the Prior Art

In the design of integrated circuits, capacitor structures play an indispensable role. Among them, MOM (Metal-Oxide-Metal) capacitors and MIM (Metal-Insulator-Metal) capacitors are two common capacitor structures. Although MOM capacitors and MIM capacitors are both composed of metal and insulating layers, there exist significant differences in structure, process, and performance, and these differences directly affect the selection of MOM capacitors and MIM capacitors in different application scenarios.

MOM capacitors primarily utilize an oxide layer between metal of the same layer or adjacent layers as a medium, forming an interdigital electrode structure. The advantage of the interdigital electrode structure lies in a simple process, requiring no additional mask layers, and the interdigital electrode structure can fully utilize existing metal interconnect layers. However, due to a relatively low dielectric constant of the oxide layer and large parasitic capacitance, the capacitance value of MOM capacitors is usually small, and frequency characteristics of MOM capacitors are also relatively limited. Despite this, MOM capacitors are still widely used in digital circuits, such as coupling capacitors and bypass capacitors.

MIM capacitors, on the other hand, adopt metal of different layers with an insulating layer of high dielectric constant sandwiched in between. The advantage of the structure of MIM capacitors lies in a large capacitance value, excellent frequency characteristics, and relatively stable capacitance value. However, the process of MIM capacitors is relatively complex, requiring additional mask layers and additional process steps. Furthermore, the insulating layer with high dielectric constant may introduce large leakage current, which affects the performance of MIM capacitors. MIM capacitors are typically used in analog circuits, radio frequency circuits, and other applications requiring high precision of capacitance value.

### SUMMARY OF THE INVENTION

The invention provides a capacitor structure, and the capacitor structure comprises a substrate, wherein a left region, a middle region, and a right region are defined on the substrate, wherein the middle region is located between the left region and the right region, a first capacitor structure comprises a first lower electrode pattern and a first upper electrode pattern, wherein the first lower electrode pattern and the first upper electrode pattern are located within different regions and located in different layers in a vertical direction, and a second capacitor structure comprises a second lower electrode pattern and a second upper electrode pattern, wherein the second lower electrode pattern and the second upper electrode pattern are located within different regions and located in different layers in the vertical direction.

The invention further provides a manufacturing method of a capacitor structure, and the manufacturing method comprises providing a substrate, wherein a left region, a middle region, and a right region are defined on the substrate, wherein the middle region is located between the left region and the right region, forming a first capacitor structure, and the first capacitor structure comprises a first lower electrode pattern and a first upper electrode pattern, wherein the first lower electrode pattern and the first upper electrode pattern are located within different regions and located in different layers in a vertical direction, and forming a second capacitor structure, and the second capacitor structure comprises a second lower electrode pattern and a second upper electrode pattern, wherein the second lower electrode pattern and the second upper electrode pattern are located within different regions and located in different layers in the vertical direction.

The feature of the invention lies in providing a paired capacitor and a manufacturing method thereof, wherein the paired capacitor is composed of two capacitor structures, and each of the two capacitor structures comprises a plurality of layers of MOM electrode patterns. Wherein, along the vertical direction, the respective MOM electrode patterns of the two capacitor structures are alternately stacked in different regions, and the respective MOM electrode patterns are connected to each other by a plurality of contact plugs. Therefore, the invention can effectively reduce the difference in capacitance values of electrode patterns within different regions, thereby enhancing the quality of the paired capacitor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following description easier to understand, a plurality of drawings and detailed descriptions thereof may be referred to simultaneously while reading the invention. Through specific embodiments in the present disclosure and with reference to the corresponding drawings, the specific embodiments of the invention are explained in detail, and the specific embodiments are used to illustrate operating principles of the specific embodiments of the invention. Additionally, for the sake of clarity, features in the drawings may not be drawn to actual scale, and therefore, dimensions of some features in some drawings may be intentionally enlarged or reduced.

FIG. 1 illustrates a top-view schematic diagram of a plurality of electrode patterns of a paired capacitor according to a first embodiment of the invention.

FIG. 2 illustrates a three-dimensional schematic diagram of a paired capacitor according to a second embodiment of the invention.

FIG. 3 illustrates a top-view schematic diagram of a plurality of lower electrode patterns of a paired capacitor according to a third embodiment of the invention.

FIG. 4 illustrates a top-view schematic diagram of a plurality of upper electrode patterns of a paired capacitor according to the third embodiment of the invention.

FIG. 5 illustrates a three-dimensional schematic diagram of a paired capacitor according to the third embodiment of the invention.

FIG. 6 illustrates a three-dimensional schematic diagram of a paired capacitor according to a fourth embodiment of the invention.

### DETAILED DESCRIPTION

Despite the discussion of specific configurations and specific arrangements herein, it should be understood that the discussion of specific configurations and specific arrangements is completed solely for illustrative purposes. Persons skilled in the relevant art will recognize that other configurations and other arrangements can be used without departing from the spirit and scope of the present disclosure. It will be apparent to persons skilled in the relevant art that the present disclosure can also be used in a plurality of various other applications.

It should be noted that references in the specification to “one embodiment,” “an embodiment,” “an example embodiment,” “some embodiments,” and the like indicate that the embodiment described may include a specific feature, a specific structure, or a specific characteristic, but each embodiment may not necessarily include the specific feature, the specific structure, or the specific characteristic. Moreover, phrases such as “one embodiment,” “an embodiment,” “an example embodiment,” and “some embodiments” do not necessarily refer to the same embodiment. Furthermore, when a specific feature, a specific structure, or a specific characteristic is described in connection with an embodiment, regardless of whether explicitly described, it is within the knowledge of persons skilled in the relevant art to achieve the specific feature, the specific structure, or the specific characteristic in connection with other embodiments.

Typically, terminology can be understood at least in part based on usage in context. For example, the term “one or more” as used herein (depending at least in part on context) may be used to describe any feature, any structure, or any characteristic in a singular sense or may be used to describe combinations of features, structures, or characteristics in a plural sense. Similarly, terms such as “a,” “an,” or “the” may again be understood to convey singular usage or to convey plural usage, depending at least in part on context. Furthermore, the term “based on” may be understood as not necessarily intended to convey an exclusive set of factors and may, conversely, allow existence of additional factors not explicitly described, depending at least in part on context.

It should be readily understood that meanings of “on . . . ,” “above . . . ,” and “over . . . ” in the present disclosure should be interpreted in the broadest manner, such that “on . . . ” not only means “directly on something” but also includes the meaning of “on something” with an intermediate feature or an intermediate layer therebetween, and that “above . . . ” or “over . . . ” not only means the meaning of “above something” or “over something” but can also include the meaning of “above something” or “over something” with no intermediate feature or no intermediate layer therebetween (i.e., directly on something).

Furthermore, for ease of description, a plurality of spatially relative terms such as “beneath . . . ,” “below . . . ,” “lower,” “above . . . ,” “upper,” and the like may be used herein to describe a relationship of one element or one feature to another element (one or more elements) or another feature (one or more features) as illustrated in the figures. In addition to orientations depicted in the figures, the plurality of spatially relative terms are intended to encompass different orientations of elements in use or in operation. The device may be oriented in other ways (rotated 90 degrees or at other orientations), and the plurality of spatially relative descriptions used herein may be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide variety of semiconductor materials, such as silicon, germanium, gallium arsenide, indium phosphide, and the like. Alternatively, the substrate can be made of non-conductive material, such as glass, plastic, or a sapphire wafer.

As used herein, the term “layer” refers to a material portion including a region with a thickness. A layer can extend over an entirety of an underlying structure or an overlying structure, or a layer may have an extent less than an extent of an underlying structure or an overlying structure. Furthermore, a layer can be a region of a uniform or non-uniform continuous structure that has a thickness less than a thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, a substrate can include one or more layers therein, and/or a substrate can have one or more layers thereupon, thereabove, and/or therebelow. A layer can include a plurality of layers. For example, an interconnect layer can include one or more conductor layers and one or more contact layers (wherein a plurality of contacts, a plurality of interconnect lines, and/or a plurality of vias are formed) and one or more dielectric layers.

As described in the prior art, in the design of integrated circuits, capacitor structures are widely applied. Among them, MOM (Metal-Oxide-Metal) capacitors can be fabricated together with a plurality of conductive layers of electronic components, and therefore, in electronic components with smaller volume, MOM capacitors are often used as primary capacitor structures. Additionally, a paired capacitor is a circuit element that includes two capacitor structures. Wherein, in an ideal state, the two capacitor structures included in the paired capacitor have identical capacitance values, and therefore, signal magnitudes outputted by the two capacitor structures are also identical. The paired capacitor can be applied in a plurality of various electronic products, for example, the paired capacitor can be applied in headphones (to ensure that sound magnitudes outputted by left and right sides of the headphones are consistent), or the paired capacitor can be applied in a plurality of other circuits, such as differential circuits, filter circuits, coupling circuits, and the like.

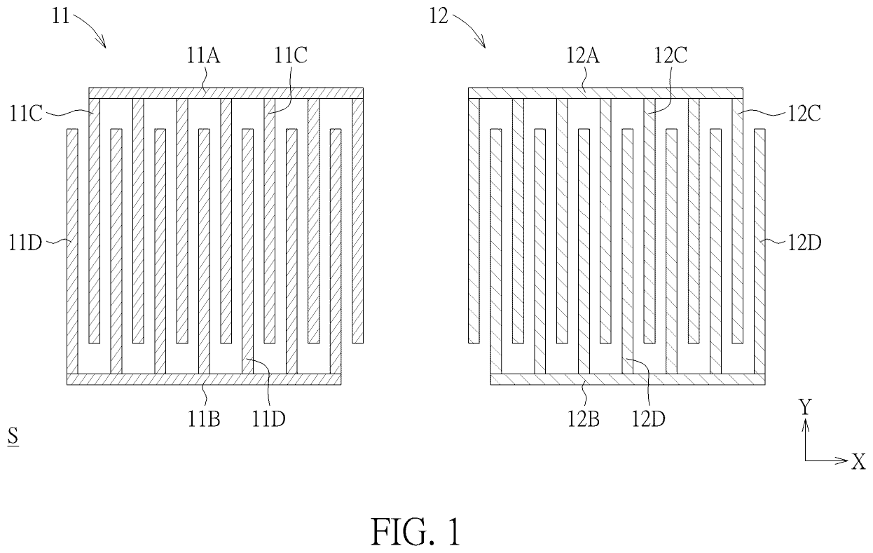

In order to ensure that two capacitor structures of a paired capacitor have capacitance values as identical as possible, typically, a plurality of identical capacitor patterns are fabricated to serve as the two capacitor structures in the paired capacitor respectively. FIG. 1 illustrates a top-view schematic diagram of a plurality of electrode patterns of a paired capacitor according to a first embodiment of the invention. As shown in FIG. 1, a paired capacitor 1 comprises a first electrode pattern 11 and a second electrode pattern 12, wherein the first electrode pattern 11 is located on a left side in the figure, and the second electrode pattern 12 is located on a right side in the figure, wherein the first electrode pattern 11 and the second electrode pattern 12, together with a surrounding dielectric layer (not shown in the figure), can respectively constitute one capacitor structure, that is to say, the paired capacitor 1 is composed of one capacitor structure on the left side and one capacitor structure on the right side. Wherein, in some embodiments of the invention, the first electrode pattern 11 and the second electrode pattern 12 are preferably identical to each other or similar to each other in pattern. Taking the present embodiment as an example, the first electrode pattern 11 comprises a plurality of main spine electrodes 11A and 11B and a plurality of branch electrodes 11C and 11D arranged parallel to each other, wherein the main spine electrode 11A and the main spine electrode 11B are arranged along a first direction (for example, the X direction) and are respectively located at a position near a top and a position near a bottom in FIG. 1, and the plurality of branch electrodes 11C and the plurality of branch electrodes 11D are arranged along a second direction (for example, the Y direction), wherein each of the branch electrodes 11C is connected to the main spine electrode 11A located at the position near the top, and each of the branch electrodes 11D is connected to the main spine electrode 11B located at the position near the bottom. Additionally, when viewed along the X direction, the branch electrodes 11C and the branch electrodes 11D are alternately arranged, for example, the branch electrodes 11C and the branch electrodes 11D are arranged in an order of the branch electrode 11C, the branch electrode 11D, the branch electrode 11C, the branch electrode 11D, and so forth. Lengths of the branch electrodes 11C and the branch electrodes 11D in the Y direction are preferably identical to each other. Here, the plurality of main spine electrodes 11A and 11B and the plurality of branch electrodes 11C and 11D are all constituted by material with good conductivity (for example, metal) to form an electrode pattern. Therefore, the first electrode pattern 11 comprises the plurality of main spine electrodes 11A and 11B and the plurality of branch electrodes 11C and 11D constituted by conductive material, and the first electrode pattern 11 constitutes an interdigital electrode pattern. Wherein, the interdigital electrode pattern is located in a dielectric layer (not shown in the figure), and the interdigital electrode pattern serves as a conductive layer of an MOM capacitor structure, while the dielectric layer serves as an oxide layer of the MOM capacitor structure.

Similarly, the second electrode pattern 12 has a structure similar to a structure of the first electrode pattern 11, wherein the second electrode pattern 12 comprises a plurality of main spine electrodes 12A and 12B and a plurality of branch electrodes 12C and 12D arranged parallel to each other, wherein the main spine electrode 12A and the main spine electrode 12B are arranged along the first direction (for example, the X direction) and are respectively located at a position near the top and a position near the bottom in FIG. 1, and the plurality of branch electrodes 12C and the plurality of branch electrodes 12D are arranged along the second direction (for example, the Y direction), wherein each of the branch electrodes 12C is connected to the main spine electrode 12A located at the position near the top, and each of the branch electrodes 12D is connected to the main spine electrode 12B located at the position near the bottom. Additionally, when viewed along the X direction, the branch electrodes 12C and the branch electrodes 12D are alternately arranged, for example, from a left side to a right side, the branch electrodes 12C and the branch electrodes 12D are arranged in an order of the branch electrode 12C, the branch electrode 12D, the branch electrode 12C, the branch electrode 12D, and so forth. Lengths of the branch electrodes 12C and the branch electrodes 12D in the Y direction are preferably identical to each other. Here, the plurality of main spine electrodes 12A and 12B and the plurality of branch electrodes 12C and 12D are all constituted by material with good conductivity (for example, metal) to form an electrode pattern. Therefore, the second electrode pattern 12 comprises the plurality of main spine electrodes 12A and 12B and the plurality of branch electrodes 12C and 12D constituted by conductive material, and the second electrode pattern 12 constitutes an interdigital electrode pattern. Wherein, the interdigital electrode pattern is located in a dielectric layer (not shown in the figure), and the interdigital electrode pattern serves as a conductive layer of an MOM capacitor structure, while the dielectric layer serves as an oxide layer of the MOM capacitor structure.

The paired capacitor 1 is constituted by the above-described first electrode pattern 11 and the above-described second electrode pattern 12 together, and the paired capacitor 1 can be applied in a plurality of various circuits as mentioned previously. It is worth noting that, if a capacitance value of a capacitor structure is to be increased, one of methods is to increase an area of an electrode pattern, because a capacitance value is proportional to an area of an electrode pattern, that is to say, the larger an area of an electrode pattern, the higher a capacitance value of a capacitor structure.

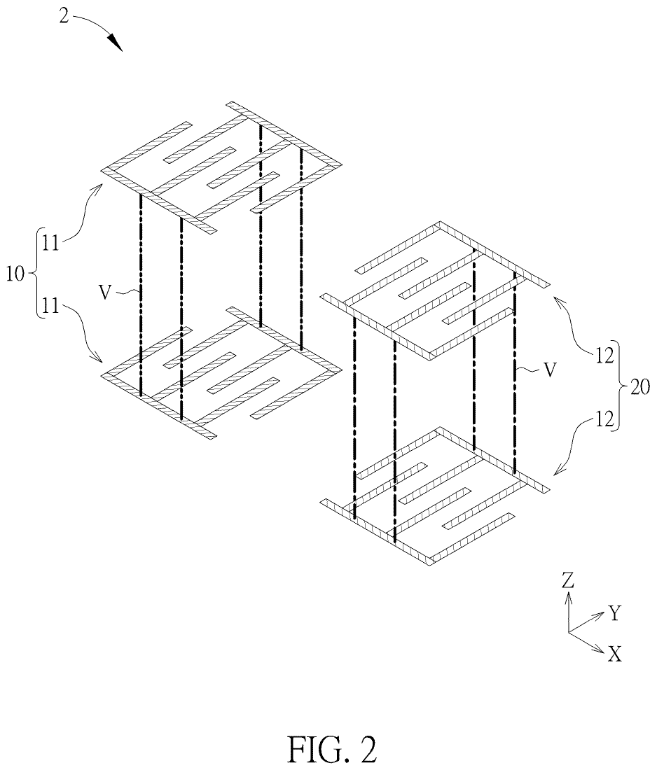

However, due to gradual miniaturization of electronic products, components of electronic products are often restricted by space and cannot excessively increase an area. At this time, a plurality of electrode patterns can be stacked, and the plurality of electrode patterns of different layers can be electrically connected to each other to increase a total capacitance value of a capacitor structure. FIG. 2 illustrates a three-dimensional schematic diagram of a paired capacitor according to a second embodiment of the invention. As shown in FIG. 2, a paired capacitor 2 comprises a left capacitor structure 10 and a right capacitor structure 20, wherein the left capacitor structure 10 comprises a plurality of layers of electrode patterns stacked with each other, for example, the above-described first electrode pattern 11 is repeatedly formed multiple times and disposed in different layers in a Z-axis direction, and the plurality of first electrode patterns 11 of the respective layers are electrically connected to each other by a plurality of contact plugs V. Similarly, the right capacitor structure 20 also comprises a plurality of layers of electrode patterns stacked with each other, for example, the above-described second electrode pattern 12 is repeatedly formed multiple times and disposed in different layers in the Z-axis direction, and the plurality of second electrode patterns 12 of the respective layers are electrically connected to each other by the plurality of contact plugs V. In this way, a total capacitance value of the left capacitor structure 10 and a total capacitance value of the right capacitor structure 20 will be equal to a sum of capacitance values of the plurality of electrode layers included therein, and in this way, a capacitance value can be effectively increased, and the left capacitor structure 10 and the right capacitor structure 20 can be applied in electronic products requiring higher capacitance values. It is worth noting that, although FIG. 2 depicts only two layers of the plurality of first electrode patterns 11 and two layers of the plurality of second electrode patterns 12, it can be understood that the invention can increase more layers of electrode patterns according to actual needs to constitute a capacitor structure with a higher capacitance value, and this also falls within the scope of the invention.

In the above embodiment, the paired capacitor 2 with a higher capacitance value is formed, and although in an ideal state, the left capacitor structure 10 and the right capacitor structure 20 have identical capacitance values, in an actual process, due to a plurality of various errors such as process conditions, a capacitance value of the left capacitor structure 10 and a capacitance value of the right capacitor structure 20 may have slight differences. That is to say, a capacitance value of the left capacitor structure 10 and a capacitance value of the right capacitor structure 20 are not completely identical, and there exists a capacitance difference between a capacitance value of the left capacitor structure 10 and a capacitance value of the right capacitor structure 20. Here, a situation where a capacitance value of the above-described left capacitor structure 10 and a capacitance value of the above-described right capacitor structure 20 are not completely identical is defined as capacitance mismatch. A reason for the capacitance mismatch may be due to errors in a process, which cause a plurality of various conditions (such as area, thickness, distance, and the like) of the first electrode pattern 11 and the second electrode pattern 12 to be different, and therefore, capacitance values of the corresponding electrode patterns are also different. For example, if due to errors in a process, an area of the formed first electrode pattern 11 is slightly larger than an area of the second electrode pattern 12, this will result in a capacitance value of the first electrode pattern 11 being slightly larger than a capacitance value of the second electrode pattern 12. Particularly, when the plurality of first electrode patterns 11 and the plurality of second electrode patterns 12 are stacked to form the left capacitor structure 10 and the right capacitor structure 20 respectively as shown in FIG. 2, a capacitance value difference between capacitor structures on a left side and a right side will gradually increase, and therefore, the above-described capacitance mismatch situation will become more pronounced.

To solve these issues of the above-described capacitance mismatch, in the following embodiments, the invention proposes a plurality of other embodiments of a paired capacitor. Compared to the above-described embodiments, paired capacitors in the following embodiments have a relatively special structure, and the paired capacitors in the following embodiments can effectively reduce a problem of the capacitance mismatch. Details are as described in the following paragraphs.

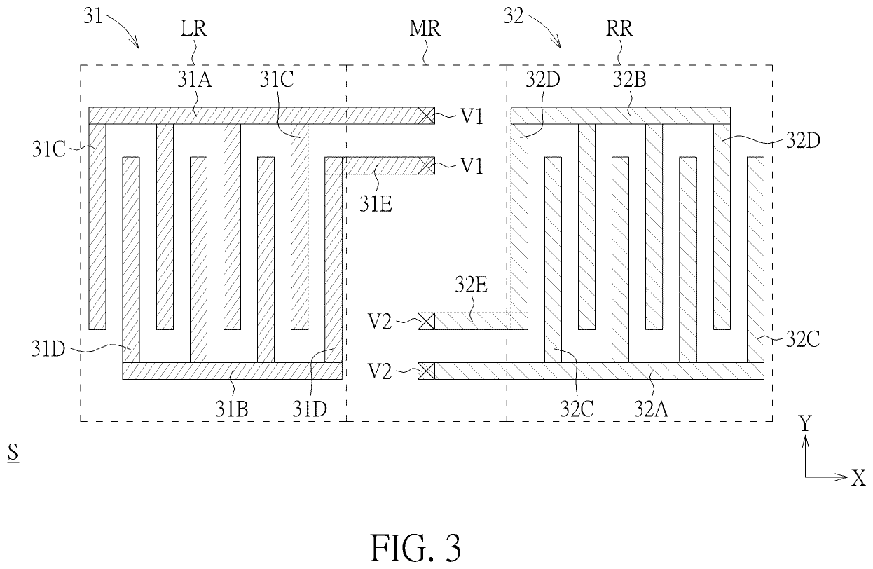

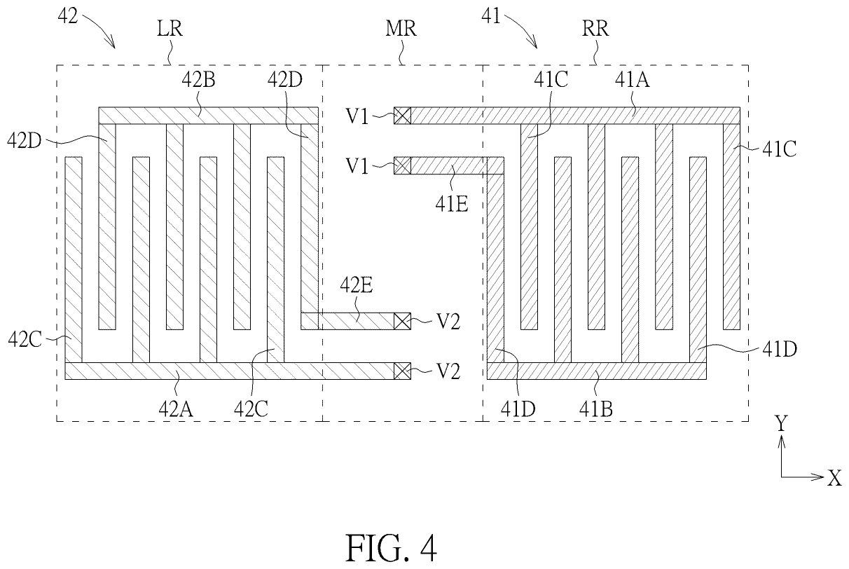

FIG. 3 illustrates a top-view schematic diagram of a plurality of lower electrode patterns of a paired capacitor according to a third embodiment of the invention, and FIG. 4 illustrates a top-view schematic diagram of a plurality of upper electrode patterns of a paired capacitor according to the third embodiment of the invention. As shown in FIG. 3 and FIG. 4, a paired capacitor comprises a substrate S, and a first lower electrode pattern 31, a second lower electrode pattern 32, a first upper electrode pattern 41, and a second upper electrode pattern 42 are on the substrate S. The first lower electrode pattern 31 and the second lower electrode pattern 32 described here have a structure similar to a structure of the first electrode pattern 11 or a structure of the second electrode pattern 12 in the above-described first embodiment. In more detail, the first lower electrode pattern 31 comprises a plurality of main spine electrodes 31A and 31B, a plurality of branch electrodes 31C and 31D arranged parallel to each other, and a connecting electrode 31E, wherein the main spine electrode 31A, the main spine electrode 31B, and the connecting electrode 31E are arranged along a first direction (for example, an X direction), and the plurality of branch electrodes 31C and the plurality of branch electrodes 31D are arranged along a second direction (for example, a Y direction), wherein each of the branch electrodes 31C is connected to the main spine electrode 31A, and each of the branch electrodes 31D is connected to the main spine electrode 31B. Additionally, when viewed along the X direction, the branch electrodes 31C and the branch electrodes 31D are alternately arranged. Lengths of the branch electrodes 31C and the branch electrodes 31D in the Y direction are preferably identical to each other. Here, the plurality of main spine electrodes 31A and 31B, the plurality of branch electrodes 31C and 31D, and the connecting electrode 31E are all constituted by material with good conductivity (for example, metal) to form an electrode pattern. Therefore, the first lower electrode pattern 31 comprises the plurality of main spine electrodes 31A and 31B, the plurality of branch electrodes 31C and 31D, and the connecting electrode 31E constituted by conductive material, and the first lower electrode pattern 31 constitutes an interdigital electrode pattern. Wherein, the interdigital electrode pattern is located in a dielectric layer (not shown in the figure), and the interdigital electrode pattern serves as a conductive layer of an MOM capacitor structure, while the dielectric layer serves as an oxide layer of the MOM capacitor structure. It is worth noting that, in the present embodiment, a length of the main spine electrode 31A is greater than a length of the main spine electrode 31B, and the connecting electrode 31E connects an end of the branch electrode 31D that is closest to the second lower electrode pattern 32. Furthermore, the first lower electrode pattern 31 further comprises a contact plug V1, and in the present embodiment, the contact plug V1 is located on the main spine electrode 31A and the connecting electrode 31E, and the contact plug V1 is used to connect the first lower electrode pattern 31 to the first upper electrode pattern 41 of another layer (which will be further described in the subsequent paragraphs).

Similarly, the second lower electrode pattern 32 comprises a plurality of main spine electrodes 32A and 32B, a plurality of branch electrodes 32C and 32D arranged parallel to each other, and a connecting electrode 32E, wherein the main spine electrode 32A, the main spine electrode 32B, and the connecting electrode 32E are arranged along the first direction (for example, the X direction), and the plurality of branch electrodes 32C and the plurality of branch electrodes 32D are arranged along the second direction (for example, the Y direction), wherein each of the branch electrodes 32C is connected to the main spine electrode 32A, and each of the branch electrodes 32D is connected to the main spine electrode 32B. Additionally, when viewed along the X direction, the branch electrodes 32C and the branch electrodes 32D are alternately arranged. Lengths of the branch electrodes 32C and the branch electrodes 32D in the Y direction are preferably identical to each other. Here, the plurality of main spine electrodes 32A and 32B, the plurality of branch electrodes 32C and 32D, and the connecting electrode 32E are all constituted by material with good conductivity (for example, metal) to form an electrode pattern. Therefore, the second lower electrode pattern 32 comprises the plurality of main spine electrodes 32A and 32B, the plurality of branch electrodes 32C and 32D, and the connecting electrode 32E constituted by conductive material, and the second lower electrode pattern 32 constitutes an interdigital electrode pattern. Wherein, the interdigital electrode pattern is located in a dielectric layer (not shown in the figure), and the interdigital electrode pattern serves as a conductive layer of an MOM capacitor structure, while the dielectric layer serves as an oxide layer of the MOM capacitor structure. It is worth noting that, in the present embodiment, a length of the main spine electrode 32A is greater than a length of the main spine electrode 32B, and the connecting electrode 32E connects an end of the branch electrode 32D that is closest to the first lower electrode pattern 31. Furthermore, the second lower electrode pattern 32 further comprises a contact plug V2, and in the present embodiment, the contact plug V2 is located on the main spine electrode 32A and the connecting electrode 32E, and the contact plug V2 is used to connect the second lower electrode pattern 32 to the second upper electrode pattern 42 of another layer (which will be further described in the subsequent paragraphs).

It is worth noting that a left region LR, a middle region MR, and a right region RR can be defined in FIG. 3. Wherein, the left region LR comprises the plurality of branch electrodes 31C and the plurality of branch electrodes 31D of the first lower electrode pattern 31, as well as a portion of the main spine electrode 31A and a portion of the main spine electrode 31B. The right region RR comprises the plurality of branch electrodes 32C and the plurality of branch electrodes 32D of the second lower electrode pattern 32, as well as a portion of the main spine electrode 32A and a portion of the main spine electrode 32B. The middle region MR comprises a portion of the main spine electrode 31A, the connecting electrode 31E, a portion of the main spine electrode 32A, the connecting electrode 32E, and a plurality of contact plugs V1 and V2. It is worth noting that, in the present embodiment, the plurality of contact plugs V1 and the plurality of contact plugs V2 are located within the middle region MR and are not located within the left region LR or the right region RR.

Then, as shown in FIG. 4, the paired capacitor further comprises the first upper electrode pattern 41 and the second upper electrode pattern 42. The first upper electrode pattern 41 described here has a structure similar to a structure of the above-described second lower electrode pattern 32, and along a Z-axis direction, the first upper electrode pattern 41 and the second lower electrode pattern 32 are both located in the right region RR, and the first upper electrode pattern 41 is located above the second lower electrode pattern 32. In more detail, the first upper electrode pattern 41 comprises a plurality of main spine electrodes 41A and 41B, a plurality of branch electrodes 41C and 41D arranged parallel to each other, and a connecting electrode 41E, wherein the main spine electrode 41A, the main spine electrode 41B, and the connecting electrode 41E are arranged along the first direction (for example, the X direction), and the plurality of branch electrodes 41C and the plurality of branch electrodes 41D are arranged along the second direction (for example, the Y direction), wherein each of the branch electrodes 41C is connected to the main spine electrode 41A, and each of the branch electrodes 41D is connected to the main spine electrode 41B. Additionally, when viewed along the X direction, the branch electrodes 41C and the branch electrodes 41D are alternately arranged. Lengths of the branch electrodes 41C and the branch electrodes 41D in the Y direction are preferably identical to each other. Here, the plurality of main spine electrodes 41A and 41B, the plurality of branch electrodes 41C and 41D, and the connecting electrode 41E are all constituted by material with good conductivity (for example, metal) to form an electrode pattern. Therefore, the first upper electrode pattern 41 comprises the plurality of main spine electrodes 41A and 41B, the plurality of branch electrodes 41C and 41D, and the connecting electrode 41E constituted by conductive material, and the first upper electrode pattern 41 constitutes an interdigital electrode pattern. Wherein, the interdigital electrode pattern is located in a dielectric layer (not shown in the figure), and the interdigital electrode pattern serves as a conductive layer of an MOM capacitor structure, while the dielectric layer serves as an oxide layer of the MOM capacitor structure. Furthermore, the first upper electrode pattern 41 is electrically connected to the first lower electrode pattern 31 through the plurality of contact plugs V1.

Similarly, the second upper electrode pattern 42 described here has a structure similar to a structure of the above-described first lower electrode pattern 31, and along the Z-axis direction, the second upper electrode pattern 42 and the first lower electrode pattern 31 are both located in the left region LR, and the second upper electrode pattern 42 is located above the first lower electrode pattern 31. In more detail, the second upper electrode pattern 42 comprises a plurality of main spine electrodes 42A and 42B, a plurality of branch electrodes 42C and 42D arranged parallel to each other, and a connecting electrode 42E, wherein the main spine electrode 42A, the main spine electrode 42B, and the connecting electrode 42E are arranged along the first direction (for example, the X direction), and the plurality of branch electrodes 42C and the plurality of branch electrodes 42D are arranged along the second direction (for example, the Y direction), wherein each of the branch electrodes 42C is connected to the main spine electrode 42A, and each of the branch electrodes 42D is connected to the main spine electrode 42B. Additionally, when viewed along the X direction, the branch electrodes 42C and the branch electrodes 42D are alternately arranged. Lengths of the branch electrodes 42C and the branch electrodes 42D in the Y direction are preferably identical to each other. Here, the plurality of main spine electrodes 42A and 42B, the plurality of branch electrodes 42C and 42D, and the connecting electrode 42E are all constituted by material with good conductivity (for example, metal) to form an electrode pattern. Therefore, the second upper electrode pattern 42 comprises the plurality of main spine electrodes 42A and 42B, the plurality of branch electrodes 42C and 42D, and the connecting electrode 42E constituted by conductive material, and the second upper electrode pattern 42 constitutes an interdigital electrode pattern. Wherein, the interdigital electrode pattern is located in a dielectric layer (not shown in the figure), and the interdigital electrode pattern serves as a conductive layer of an MOM capacitor structure, while the dielectric layer serves as an oxide layer of the MOM capacitor structure. Furthermore, the second upper electrode pattern 42 is electrically connected to the second lower electrode pattern 32 through the plurality of contact plugs V2.

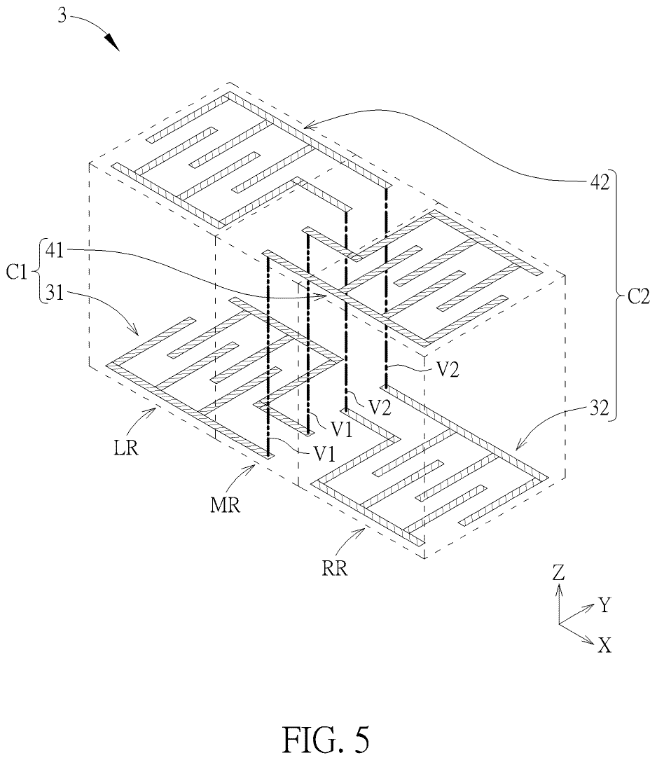

FIG. 5 illustrates a three-dimensional schematic diagram of a paired capacitor according to the third embodiment of the invention. As shown in FIG. 5, a paired capacitor 3 comprises a first capacitor structure C1 and a second capacitor structure C2. Wherein, the first capacitor structure C1 comprises the first lower electrode pattern 31 and the first upper electrode pattern 41 electrically connected to each other through the plurality of contact plugs V1, and the second capacitor structure C2 comprises the second lower electrode pattern 32 and the second upper electrode pattern 42 electrically connected to each other through the plurality of contact plugs V2. It is worth noting that, unlike the paired capacitor 2 in the second embodiment where the left capacitor structure 10 and the right capacitor structure 20 are completely separated into a left side and a right side, in the paired capacitor 3 of the present embodiment, the first lower electrode pattern 31 of the first capacitor structure C1 is located in the left region LR, while the first upper electrode pattern 41 of the first capacitor structure C1 is located in the right region RR, and conversely, the second lower electrode pattern 32 of the second capacitor structure C2 is located in the right region RR, while the second upper electrode pattern 42 of the second capacitor structure C2 is located in the left region LR. That is to say, the plurality of electrode patterns of the first capacitor structure C1 and the second capacitor structure C2 are alternately arranged in the left region LR and the right region RR along the Z-axis direction (vertical direction). The advantage of this arrangement is that it can effectively reduce a problem of the capacitance mismatch. For example, assuming that due to process errors, a capacitance value of an electrode pattern in the left region LR is X1, and a capacitance value of an electrode pattern in the right region RR is X2, wherein X1 is greater than X2, then in the paired capacitor 2 of the second embodiment, a total capacitance value of the left capacitor structure 10 would be 2X1 (because both layers of the plurality of electrode patterns are in the left region LR), and a total capacitance value of the right capacitor structure 20 would be 2 X2 (because both layers of the plurality of electrode patterns are in the right region RR), resulting in a capacitance difference of 2X1−2X2=2(X1−X2), which indicates a relatively large capacitance mismatch. If the structure shown in FIG. 2 above is used, stacking the multiple electrode patterns in the left region LR and the right region RR respectively would result in a gradually increasing capacitance difference between the capacitance structure of the left region and that of the right region. This is because the capacitance value X1 of each layer is slightly greater than the capacitance value X2. Theoretically, after stacking N layers, the capacitance difference would become N*(X1−X2). However, in the paired capacitor 3 of the present embodiment, a total capacitance value of the first capacitor structure C1 would be X1+X2 (because the first lower electrode pattern 31 is in the left region LR and the first upper electrode pattern 41 is in the right region RR), and a total capacitance value of the second capacitor structure C2 would also be X1+X2 (because the second lower electrode pattern 32 is in the right region RR and the second upper electrode pattern 42 is in the left region LR), resulting in a capacitance difference of (X1+X2)−(X1+X2)=0, which indicates that the capacitance mismatch is completely eliminated. Therefore, by alternately arranging the plurality of electrode patterns of two capacitor structures in different regions, the invention can effectively reduce a difference in capacitance values caused by process errors, thereby enhancing the quality of the paired capacitor 3.

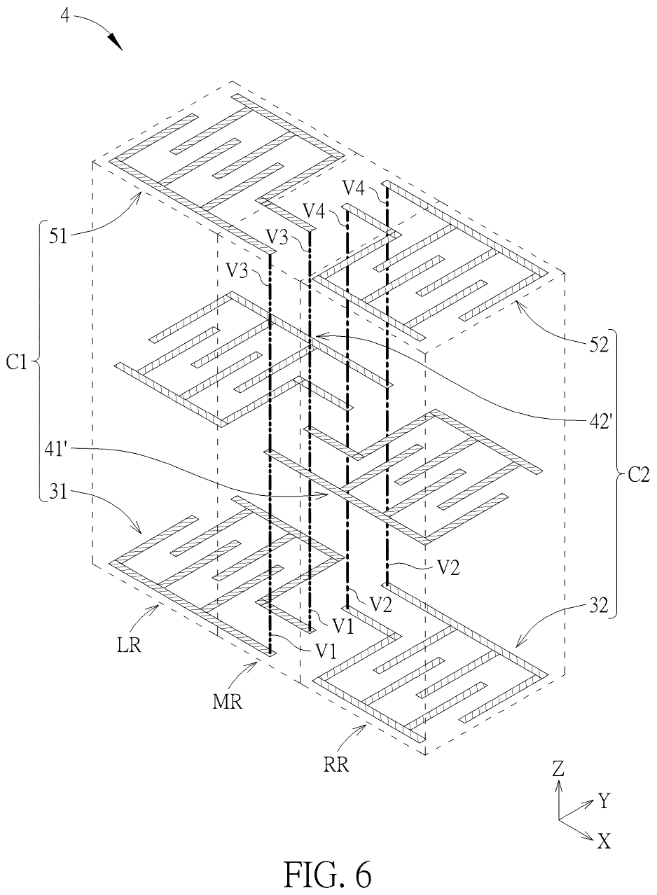

It is worth noting that, although the third embodiment shown in FIG. 5 only includes two layers of the plurality of electrode patterns in each capacitor structure (i.e., the first lower electrode pattern 31 and the first upper electrode pattern 41 in the first capacitor structure C1, and the second lower electrode pattern 32 and the second upper electrode pattern 42 in the second capacitor structure C2), the invention is not limited to two layers. FIG. 6 illustrates a three-dimensional schematic diagram of a paired capacitor according to a fourth embodiment of the invention. It is worth noting that, although in the above third embodiment (shown in FIG. 3 to FIG. 5) only upper and lower two layers of the plurality of electrode patterns are depicted, in other embodiments of the invention, more layers of electrode patterns can also be stacked to form a paired capacitor with a higher capacitance value. FIG. 6 illustrates a three-dimensional schematic diagram of a paired capacitor according to the fourth embodiment of the invention. A plurality of electrode pattern stacking can be continued to be formed on the paired capacitor shown in FIG. 5 to constitute a paired capacitor as shown in FIG. 6. In more detail, a paired capacitor 4 shown in FIG. 6 comprises a first capacitor structure C1 and a second capacitor structure C2, wherein the first capacitor structure C1 comprises a first lower electrode pattern 31, a first middle electrode pattern 41′, a first upper electrode pattern 51, and a surrounding dielectric layer, wherein each of the plurality of electrode patterns included in the above-described first capacitor structure C1 is electrically connected to each other by a plurality of contact plugs V1 and V3. The second capacitor structure C2 comprises a second lower electrode pattern 32, a second middle electrode pattern 42′, a second upper electrode pattern 52, and a surrounding dielectric layer, wherein each of the plurality of electrode patterns included in the above-described second capacitor structure C2 is electrically connected to each other by a plurality of contact plugs V2 and V4. The first lower electrode pattern 31, the second lower electrode pattern 32, the first middle electrode pattern 41′, and the second middle electrode pattern 42′ described here are respectively the same as the first lower electrode pattern 31, the second lower electrode pattern 32, the first upper electrode pattern 41, and the second upper electrode pattern 42 of the previous embodiment, and detailed descriptions thereof are not repeated here. As for the first upper electrode pattern 51, it has a shape pattern similar or identical to a shape pattern of the first lower electrode pattern 31 and is located in the left region LR, and the second upper electrode pattern 52 has a shape pattern similar or identical to a shape pattern of the second lower electrode pattern 32 and is located in the right region RR. That is to say, in the left region LR, along a Z-axis direction, the first lower electrode pattern 31, the second middle electrode pattern 42′, and the first upper electrode pattern 51 are sequentially included, and in the right region RR, along the Z-axis direction, the second lower electrode pattern 32, the first middle electrode pattern 41′, and the second upper electrode pattern 52 are sequentially included. More specifically, in the left region LR and in the right region RR, each of the plurality of electrode patterns included in the first capacitor structure C1 and each of the plurality of electrode patterns included in the second capacitor structure C2 are alternately stacked. It can be understood that, in other embodiments of the invention, based on the paired capacitor shown in FIG. 6, more layers of electrode pattern stacking can continue to be formed thereon, and an arrangement manner thereof also follows a rule described above. For example, in a left region, from bottom to top, a first electrode pattern, a second electrode pattern, the first electrode pattern, the second electrode pattern, and so forth are sequentially included, and in a right region, from bottom to top, a second electrode pattern, a first electrode pattern, the second electrode pattern, the first electrode pattern, and so forth are sequentially included.

According to the above description and the plurality of drawings, the invention provides a paired capacitor comprising a substrate S with a left region LR, a middle region MR, and a right region RR defined thereon, wherein the middle region MR is located between the left region LR and the right region RR, a first capacitor structure C1 comprising a first lower electrode pattern 31 and a first upper electrode pattern 41, wherein the first lower electrode pattern 31 and the first upper electrode pattern 41 are located in different regions and in different layers along a vertical direction, and a second capacitor structure C2 comprising a second lower electrode pattern 32 and a second upper electrode pattern 42, wherein the second lower electrode pattern 32 and the second upper electrode pattern 42 are located in different regions and in different layers along the vertical direction.

In some embodiments, the first lower electrode pattern 31 is located in the left region LR, the first upper electrode pattern 41 is located in the right region RR, the second lower electrode pattern 32 is located in the right region RR, and the second upper electrode pattern 42 is located in the left region LR.

In some embodiments, the first lower electrode pattern 31, the first upper electrode pattern 41, the second lower electrode pattern 32, and the second upper electrode pattern 42 each comprise a plurality of main spine electrodes and a plurality of branch electrodes, wherein the plurality of branch electrodes of each pattern are arranged along a same direction.

In some embodiments, a paired capacitor further comprises a plurality of first contact plugs V1 and a plurality of second contact plugs V2 located in the middle region MR, wherein the plurality of first contact plugs V1 electrically connect the first lower electrode pattern 31 and the first upper electrode pattern 41, and the plurality of second contact plugs V2 electrically connect the second lower electrode pattern 32 and the second upper electrode pattern 42.

In some embodiments, the plurality of first contact plugs V1 and the plurality of second contact plugs V2 are not located in the left region LR or the right region RR.

In some embodiments, the plurality of first contact plugs V1 electrically connect a main spine electrode of the first lower electrode pattern 31 and a main spine electrode of the first upper electrode pattern 41, and the plurality of second contact plugs V2 electrically connect a main spine electrode of the second lower electrode pattern 32 and a main spine electrode of the second upper electrode pattern 42.

In some embodiments, from a top view, the first lower electrode pattern 31 partially overlaps with the second upper electrode pattern 42, and the second lower electrode pattern 32 partially overlaps with the first upper electrode pattern 41.

In some embodiments, the first capacitor structure C1 further comprises a third-layer electrode pattern 51 located above the second upper electrode pattern 42.

In some embodiments, along the vertical direction, the third-layer electrode pattern 51, the second upper electrode pattern 42, and the first lower electrode pattern 31 of the first capacitor structure C1 partially overlap with each other.

In some embodiments, a paired capacitor further comprises a plurality of third contact plugs V3 electrically connecting the third-layer electrode pattern 51 and the first upper electrode pattern 41 of the first capacitor structure C1.

The invention also provides a manufacturing method of a paired capacitor, comprising providing a substrate S with a left region LR, a middle region MR, and a right region RR defined thereon, wherein the middle region MR is located between the left region LR and the right region RR, forming a first capacitor structure C1 comprising a first lower electrode pattern 31 and a first upper electrode pattern 41, wherein the first lower electrode pattern 31 and the first upper electrode pattern 41 are located in different regions and in different layers along a vertical direction, and forming a second capacitor structure C2 comprising a second lower electrode pattern 32 and a second upper electrode pattern 42, wherein the second lower electrode pattern 32 and the second upper electrode pattern 42 are located in different regions and in different layers along the vertical direction.

The feature of the invention lies in providing a paired capacitor and a manufacturing method thereof, wherein the paired capacitor is composed of two capacitor structures, and each of the two capacitor structures comprises a plurality of layers of MOM electrode patterns. Wherein, along the vertical direction, the respective MOM electrode patterns of the two capacitor structures are alternately stacked in different regions, and the respective MOM electrode patterns are connected to each other by a plurality of contact plugs. Therefore, the invention can effectively reduce the difference in capacitance values of electrode patterns within different regions, thereby enhancing the quality of the paired capacitor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A paired capacitor comprising:
a substrate with a left region, a middle region, and a right region defined thereon, wherein the middle region is located between the left region and the right region;
a first capacitor structure comprising a first lower electrode pattern and a first upper electrode pattern, wherein the first lower electrode pattern and the first upper electrode pattern are located in different regions and in different layers along a vertical direction; and
a second capacitor structure comprising a second lower electrode pattern and a second upper electrode pattern, wherein the second lower electrode pattern and the second upper electrode pattern are located in different regions and in different layers along the vertical direction.

2. The paired capacitor according to claim 1, wherein the first lower electrode pattern is located in the left region, the first upper electrode pattern is located in the right region, the second lower electrode pattern is located in the right region, and the second upper electrode pattern is located in the left region.

3. The paired capacitor according to claim 1, wherein the first lower electrode pattern, the first upper electrode pattern, the second lower electrode pattern, and the second upper electrode pattern each comprise a plurality of main spine electrodes and a plurality of branch electrodes, wherein the plurality of branch electrodes of each pattern are arranged along a same direction.

4. The paired capacitor according to claim 3, further comprising a plurality of first contact plugs and a plurality of second contact plugs located in the middle region, wherein the plurality of first contact plugs electrically connect the first lower electrode pattern and the first upper electrode pattern, and the plurality of second contact plugs electrically connect the second lower electrode pattern and the second upper electrode pattern.

5. The paired capacitor according to claim 4, wherein the plurality of first contact plugs and the plurality of second contact plugs are not located in the left region or the right region.

6. The paired capacitor according to claim 4, wherein the plurality of first contact plugs electrically connect a main spine electrode of the first lower electrode pattern and a main spine electrode of the first upper electrode pattern, and the plurality of second contact plugs electrically connect a main spine electrode of the second lower electrode pattern and a main spine electrode of the second upper electrode pattern.

7. The paired capacitor according to claim 1, wherein, from a top view, the first lower electrode pattern partially overlaps with the second upper electrode pattern, and the second lower electrode pattern partially overlaps with the first upper electrode pattern.

8. The paired capacitor according to claim 1, wherein the first capacitor structure further comprises a third-layer electrode pattern located above the second upper electrode pattern.

9. The paired capacitor according to claim 8, wherein, along the vertical direction, the third-layer electrode pattern, the second upper electrode pattern, and the first lower electrode pattern of the first capacitor structure partially overlap with each other.

10. The paired capacitor according to claim 8, further comprising a plurality of third contact plugs electrically connecting the third-layer electrode pattern and the first upper electrode pattern of the first capacitor structure.

11. A manufacturing method of a paired capacitor, comprising:
providing a substrate with a left region, a middle region, and a right region defined thereon, wherein the middle region is located between the left region and the right region;
forming a first capacitor structure comprising a first lower electrode pattern and a first upper electrode pattern, wherein the first lower electrode pattern and the first upper electrode pattern are located in different regions and in different layers along a vertical direction; and
forming a second capacitor structure comprising a second lower electrode pattern and a second upper electrode pattern, wherein the second lower electrode pattern and the second upper electrode pattern are located in different regions and in different layers along the vertical direction.

12. The manufacturing method according to claim 11, wherein the first lower electrode pattern is formed in the left region, the first upper electrode pattern is formed in the right region, the second lower electrode pattern is formed in the right region, and the second upper electrode pattern is formed in the left region.

13. The manufacturing method according to claim 11, wherein the first lower electrode pattern, the first upper electrode pattern, the second lower electrode pattern, and the second upper electrode pattern each comprise a plurality of main spine electrodes and a plurality of branch electrodes, wherein the plurality of branch electrodes of each pattern are arranged along a same direction.

14. The manufacturing method according to claim 13, further comprising forming a plurality of first contact plugs and a plurality of second contact plugs in the middle region, wherein the plurality of first contact plugs electrically connect the first lower electrode pattern and the first upper electrode pattern, and the plurality of second contact plugs electrically connect the second lower electrode pattern and the second upper electrode pattern.

15. The manufacturing method according to claim 14, wherein the plurality of first contact plugs and the plurality of second contact plugs are not formed in the left region or the right region.

16. The manufacturing method according to claim 14, wherein the plurality of first contact plugs electrically connect a main spine electrode of the first lower electrode pattern and a main spine electrode of the first upper electrode pattern, and the plurality of second contact plugs electrically connect a main spine electrode of the second lower electrode pattern and a main spine electrode of the second upper electrode pattern.

17. The manufacturing method according to claim 11, wherein, from a top view, the first lower electrode pattern partially overlaps with the second upper electrode pattern, and the second lower electrode pattern partially overlaps with the first upper electrode pattern.

18. The manufacturing method according to claim 11, wherein forming the first capacitor structure further comprises forming a third-layer electrode pattern above the second upper electrode pattern.

19. The manufacturing method according to claim 18, wherein, along the vertical direction, the third-layer electrode pattern, the second upper electrode pattern, and the first lower electrode pattern of the first capacitor structure partially overlap with each other.

20. The manufacturing method according to claim 18, further comprising forming a plurality of third contact plugs electrically connecting the third-layer electrode pattern and the first upper electrode pattern of the first capacitor structure.
